(19) United States
(12) Patent Application Publication
(10) Pub. No.: US 2025/0294876 A1
(43) Pub. Date: Sep. 18, 2025

(54) BONDING APPARATUS AND METHOD OF MANUFACTURING DISPLAY DEVICE USING THE BONDING APPARATUS

(71) Applicant: Samsung Display Co., Ltd., Yongin-si (KR)

(72) Inventor: JOO-NYUNG JANG, Yongin-si (KR)

(21) Appl. No.: 18/937,602

(22) Filed: Nov. 5, 2024

(30) Foreign Application Priority Data
Mar. 13, 2024 (KR) 10-2024-0034881

(51) Int. Cl. H01L 27/12; H10K 59/12; H10K 71/50; H10K 71/60

(52) U.S. Cl. CPC H10D 86/0251; H10K 59/1201; H10K 71/50; H10K 71/60; H10D 86/441; H10D 86/60

(57) ABSTRACT

A bonding apparatus includes a first unit and a second unit. The first unit includes: a first temperature control part, and first fastening holes defined through the first unit and spaced apart from each other in a first direction, where the first unit has a first thermal expansion coefficient. The second unit is disposed under the first unit and is in contact with the first unit. The second unit includes a second temperature control part and second fastening holes defined through the second unit and spaced apart from each other in the first direction, where the second unit has a second thermal expansion coefficient. The bonding apparatus includes fastening members each being inserted into a corresponding first fastening hole and a corresponding second fastening hole, where the corresponding second fastening hole is aligned with the corresponding first fastening hole, and a stage disposed under the second unit.

This application claims priority to Korean Patent Application No. 10-2024-0034881, filed on Mar. 13, 2024, and all the benefits accruing therefrom under 35 U.S.C. § 119, the content of which in its entirety is herein incorporated by reference.

### BACKGROUND

### 1. Field

The present disclosure relates to a bonding apparatus usable in a manufacturing process of a display device and a method of manufacturing the display device using the bonding apparatus.

### 2. Description of Related Art

A display device generates images and provides the images to a user through a display screen thereof.

The display device includes a plurality of pixels. The pixels receive electrical signals through signal lines. A bonding process may be performed to bond a circuit member to a pad part corresponding to ends of the signal lines. The circuit member may include a data driver, a flexible circuit board, and other components.

### SUMMARY

The present disclosure provides a bonding apparatus capable of preventing thermal deformation of a press unit, which may prevent bonding defects.

The present disclosure provides a method of manufacturing a display device capable of selecting first and second units included in the bonding apparatus in consideration of a reference temperature in a bonding process or setting an appropriate reference temperature in consideration of the first and second units.

Embodiments supported by the present disclosure provide a bonding apparatus including a first unit including a first temperature control part, and first fastening holes defined through the first unit and spaced apart from each other in a first direction, wherein the first unit has a first thermal expansion coefficient, a second unit disposed under the first unit and being in contact with the first unit, the second unit including a second temperature control part, and second fastening holes defined through the second unit and spaced apart from each other in the first direction, wherein the second unit has a second thermal expansion coefficient, fastening members each being inserted into a corresponding first fastening hole among the first fastening holes and a corresponding second fastening hole among the second fastening holes, wherein the corresponding second fastening hole is aligned with the corresponding first fastening hole in the first direction, and a stage disposed under the second unit.

The first temperature control part and the second temperature control part may be configured to adjust a temperature of the first unit and a temperature of the second unit, respectively, based on a relationship between a value obtained by multiplying the first thermal expansion coefficient by a temperature variation amount of the first unit and a value obtained by multiplying the second thermal expansion coefficient by a temperature variation amount of the second unit.

The first temperature control part and the second temperature control part are configured to adjust a temperature of the first unit and a temperature of the second unit, respectively, such that a value obtained by multiplying the first thermal expansion coefficient by a temperature variation amount of the first unit ranges from about 0.9 times to about 1.1 times of a value obtained by multiplying the second thermal expansion coefficient by a temperature variation amount of the second unit.

The first temperature control part is disposed above the first fastening holes.

The second temperature control part is disposed below the second fastening holes.

The first unit and the second unit extend in the first direction.

A length of the first unit extending in the first direction is equal to a length of the second unit extending in the first direction.

The first temperature control part includes a first temperature sensor and a first resistor heating wire.

The second temperature control part includes a second temperature sensor and a second resistor heating wire.

The first temperature control part penetrates through the first unit and is disposed in the first unit.

The second temperature control part penetrates through the second unit and is disposed in the second unit.

The second unit includes a tip part defined in a lower portion of the second unit, and the tip part protrudes in a direction from the second unit toward the stage.

The tip part includes a lower surface that is flat.

The fastening members are disposed in the first fastening holes and the second fastening holes.

The first unit, the second unit, or both includes a tungsten carbide.

The bonding apparatus further includes a head part disposed on the first unit and coupled with the first unit.

An upper surface of the stage has a flat surface defined by the first direction and a second direction intersecting the first direction.

The head part is configured to reciprocate in a third direction intersecting the first direction and the second direction.

Embodiments supported by the present disclosure provide a method of manufacturing a display device. The method includes aligning a circuit member on a preliminary display panel including pads on a stage, placing a press unit including a first unit and a second unit above the circuit member, wherein the first unit includes a first temperature control part and the second unit is disposed under the first unit and includes a second temperature control part, and pressing the circuit member and the pads using the press unit in association with bonding the circuit member to the pads. The bonding of the circuit member to the pads includes adjusting a temperature of the first unit using the first temperature control part or a temperature of the second unit using the second temperature control part and moving the press unit downward based on determining each of the first unit and the second unit is at a respective reference temperature.

The adjusting of the temperature of the first unit or the temperature of the second unit is based on obtaining or maintaining a first ratio of the temperature of the second unit to the temperature of the first unit such that the first ratio ranges from about 0.9 times to about 1.1 times of a second ratio of the first thermal expansion coefficient to the second thermal expansion coefficient.

The first temperature control part includes a first temperature sensor and a first resistor heating wire.

The second temperature control part includes a second temperature sensor and a second resistor heating wire.

The adjusting of the temperature includes supplying a current to the first resistor heating wire, the second resistor heating wire, or both.

The second unit includes a tip part defined in a lower portion of the second unit and the tip part protrudes in a direction from the second unit toward the stage.

The bonding of the circuit member includes maintaining the tip part in contact with the circuit member such that the tip part transfers heat to the circuit member. Embodiments supported by the present disclosure provide a method of

manufacturing a display device. The method includes selecting a first unit among a plurality of first units and a second unit among a plurality of second units, wherein the first unit includes a first temperature control part and the second unit includes a second temperature control part, forming a press unit including the first unit and the second unit, wherein the second unit is coupled with a lower portion of the first unit, aligning a circuit member on a preliminary display panel including pads on a stage, placing the press unit above the circuit member, and moving the press unit downward in association with bonding the circuit member to the pads.

The bonding of the circuit member to the pads includes adjusting or maintaining the selected first unit according to a first reference temperature by the first temperature control part and adjusting or maintaining the selected second unit according to a second reference temperature by the second temperature control part.

The forming of the press unit includes placing the second unit on the lower portion of the first unit and inserting each of fastening members into a corresponding first fastening hole among first fastening holes defined through the first unit and spaced apart from each other in a first direction and a corresponding second fastening hole among second fastening holes defined through the second unit and spaced apart from each other in the first direction.

The first temperature control part includes a first temperature sensor and a first resistor heating wire, the second temperature control part includes a second temperature sensor and a second resistor heating wire, and the adjusting or maintaining of the first unit according to the first reference temperature includes supplying a current to the first resistor heating wire and the adjusting or maintaining of the second unit according to the second reference temperature includes supplying a current to the second resistor heating wire.

The second unit includes a tip part defined in a lower portion of the second unit, and the tip part protrudes in a direction from the second unit toward the stage.

The bonding of the circuit member to the pads includes maintaining the tip part in contact with the circuit member in the bonding of the circuit member to the pads such that the tip part transfers heat to the circuit member.

According to embodiments of the present disclosure described herein, the bonding apparatus prevents thermal deformation of the first unit and the second unit. Accordingly, the lower surface of the second unit maintains a flat surface, and thus, the bonding apparatus provides uniform pressure to an entire area of the circuit member through the flat surface of the second unit.

According to embodiments of the present disclosure, the method of manufacturing the display device may prevent thermal deformation of the first unit and the second unit of the bonding apparatus, which may prevent costs associated with replacing the first unit or the second unit due to deformation. Accordingly, for example, time and cost for replacing a deformed first unit or a deformed second unit may be reduced or eliminated.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of a bonding apparatus according to an embodiment of the present disclosure;

FIG. 2 is a side view of a press unit according to an embodiment of the present disclosure;

FIG. 3 is a side view of a first unit and a second unit before the first and second units are assembled with each other;

FIG. 4 is a side view of the first unit and the second unit after the first and second units are assembled with each other;

FIG. 5 is a perspective view of an electronic device including a display panel manufactured using the bonding apparatus illustrated in FIG. 1;

FIG. 6 is an exploded perspective view of the electronic device illustrated in FIG. 5;

FIG. 7 is a plan view of the display panel illustrated in FIG. 5;

FIG. 8 is an enlarged perspective view of a portion of the display panel illustrated in FIG. 5;

FIGS. 9 and 10 are perspective views of a bonding apparatus according to an embodiment of the present disclosure;

FIG. 11 is a side view of the bonding apparatus illustrated in FIG. 10;

FIGS. 12 and 13 are views illustrating a deformation length of a press unit;

FIGS. 14A to 14F are graphs illustrating the deformation length according to the change of a temperature and a thermal expansion coefficient of the first and second units; and

FIGS. 15 to 17 are flowcharts illustrating a method of manufacturing a display device according to an embodiment of the present disclosure.

### DETAILED DESCRIPTION

The present disclosure may be variously modified and realized in many different forms, and thus example embodiments supported by the present disclosure will be illustrated in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, the element can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, and the like may be used herein to describe various elements, these elements should not be limited by these terms. These terms are used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as, for example, “beneath”, “below”, “lower”, “above”, “upper” and the like, may be used herein for ease of description to describe one element or feature's relationship to another elements or features as illustrated in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Hereinafter, embodiments of the present disclosure will be described with reference to accompanying drawings.

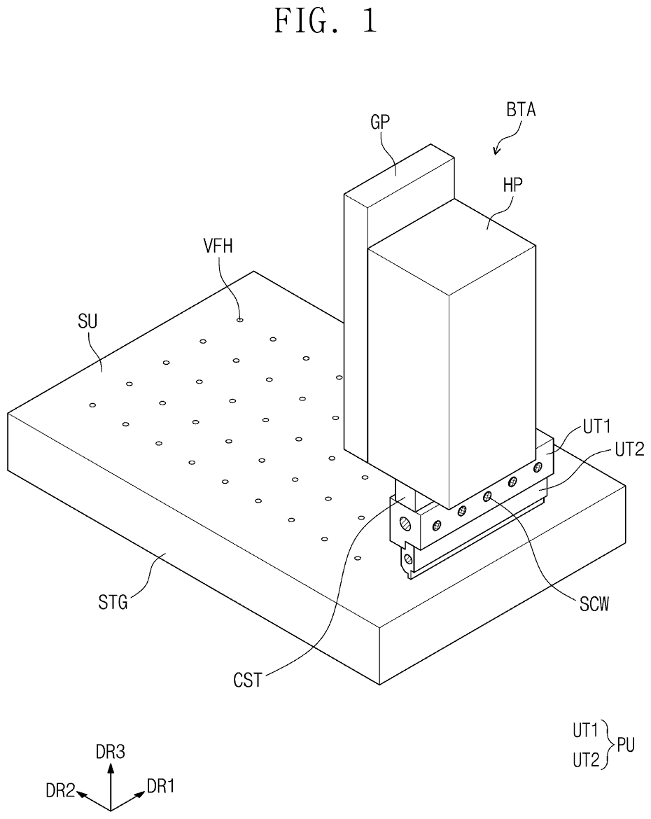

FIG. 1 is a perspective view of a bonding apparatus BTA according to an embodiment of the present disclosure.

Referring to FIG. 1, the bonding apparatus BTA may include a stage STG, a press unit PU, a connection part CST, a head part HP, and a guide part GP.

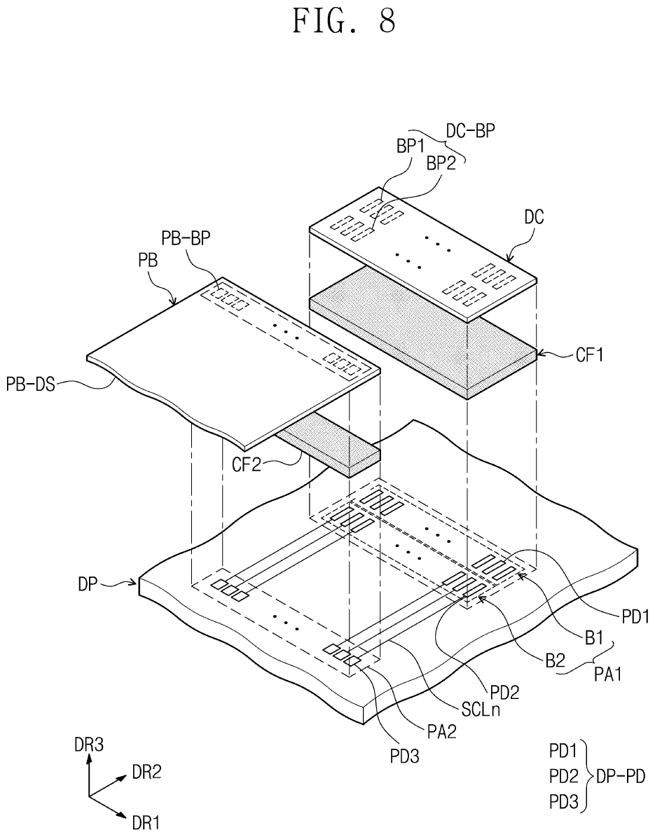

The stage STG may be disposed at a lowermost position in the bonding apparatus BTA. The stage STG may provide a flat surface on which a preliminary display panel P-DP (refer to FIG. 8) is disposed.

The stage STG may have a rectangular parallelepiped shape. When viewed on a plane, a stage upper surface SU may have a rectangular shape with short sides extending in a first direction DR1 and long sides extending in a second direction DR2 intersecting the first direction DR1. However, the shape of the stage STG or the shape of the stage upper surface SU should not be particularly limited as long as a flat upper surface on which the preliminary display panel P-DP (refer to FIG. 8) is disposed is provided.

Hereinafter, a direction substantially perpendicular to a plane defined by the first direction DR1 and the second direction DR2 may be referred to as a third direction DR3.

Suction holes VFH may be defined through the stage upper surface SU. The suction holes VFH may be arranged in the first direction DR1 and the second direction DR2. An inside of the suction holes VFH may be maintained in a vacuum state, and thus, the preliminary display panel P-DP (refer to FIG. 8) may be fixed to the stage upper surface SU.

Although not illustrated separately, the bonding apparatus BTA may further include motors to maintain the vacuum state in the suction holes VFH.

The guide part GP may be disposed on the stage STG. The guide part GP may be disposed adjacent to one side of opposite sides of the stage STG in the second direction DR2. The guide part GP may play a role in guiding a reciprocating movement of the head part HP described later. Although not illustrated separately, the guide part GP may be connected to a separate fixing member, and its position may be fixed.

The guide part GP may have a rectangular parallelepiped shape. However, the shape of the guide part GP should not be particularly limited as long as the guide part GP plays the role in guiding the reciprocating movement of the head part HP.

The head part HP may be disposed on one side of opposite sides of the guide part GP in the second direction DR2. The head part HP may be disposed on a first unit UT1 and may be coupled with the first unit UT1. The head part HP may be disposed on the stage STG and may be adjacent to one side of the stage STG.

The head part HP may reciprocate along the one side of the guide part GP in the third direction DR3. Accordingly, the press unit PU coupled with the head part HP may reciprocate in the third direction DR3.

As illustrated in FIG. 1, the head part HP has a rectangular parallelepiped shape, however, the shape of the head part HP should not be particularly limited as long as the guide part GP provides the one side on which the head part HP reciprocates along the third direction DR3.

The connection part CST may be connected to a lower surface of the head part HP. The connection part CST may be disposed between the stage STG and the head part HP. The head part HP may be connected to the press unit PU by the connection part CST.

The press unit PU may be connected to the connection part CST and may be disposed under the head part HP. Therefore, when the head part HP reciprocates in the third direction DR3, the press unit PU may reciprocate together with the head part HP in the third direction DR3.

Accordingly, the press unit PU may be directly in contact with a circuit member and may apply a pressure and heat to the circuit member in a bonding process for the preliminary display panel P-DP (refer to FIG. 8). This will be described in detail later.

The press unit PU may include the first unit UT1 and a second unit UT2 disposed under the first unit UT1.

The first unit UT1 and the second unit UT2 may be heated for the bonding process of the preliminary display panel P-DP (refer to FIG. 8). The first unit UT1 may be coupled with the second unit UT2 by a fastening member SCW.

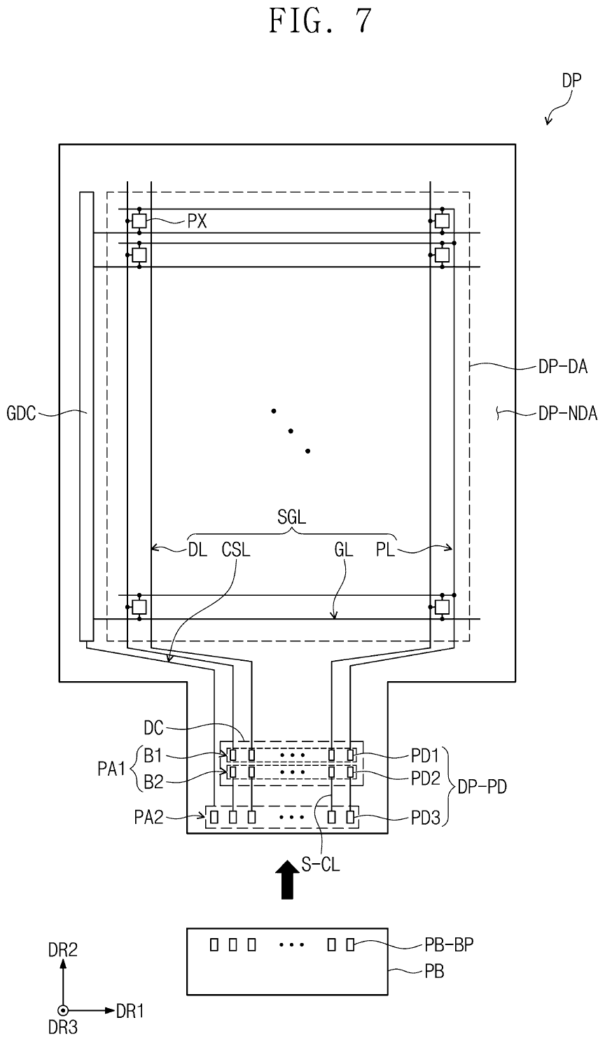

The first unit UT1 and the second unit UT2 may descend to press the circuit member after being coupled with each other by the fastening member SCW. That is, the heated first unit UT1 and the second unit UT2 may apply a target heat and pressure supportive of the bonding process to the circuit member to attach the circuit member to pads DP-PD (refer to FIG. 7).

However, when the first unit UT1 and the second unit UT2 have different thermal expansion coefficients, the shape of the press unit PU may be deformed due to a difference in thermal expansion amount between the first unit UT1 and the second unit UT2. That is, when the thermal expansion amount of the first unit UT1 is different from the thermal expansion amount of the second unit UT2, the shape of the press unit PU may be deformed.

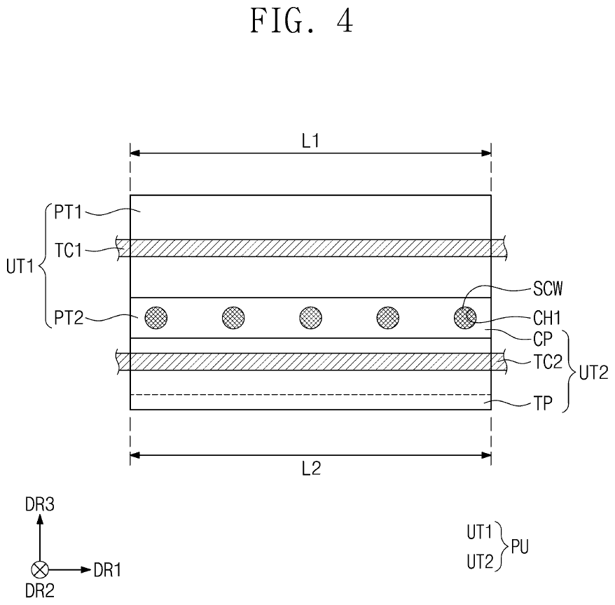

Hereinafter, the bonding apparatus BTA that prevents the deformation of the press unit PU in the bonding process by controlling a temperature of each of the first unit UT1 and the second unit UT2 using temperature control parts TC1 and TC2 (refer to FIG. 4) respectively included in the first unit UT1 and the second unit UT2 and a method of manufacturing a display device using the bonding apparatus will be described in detail.

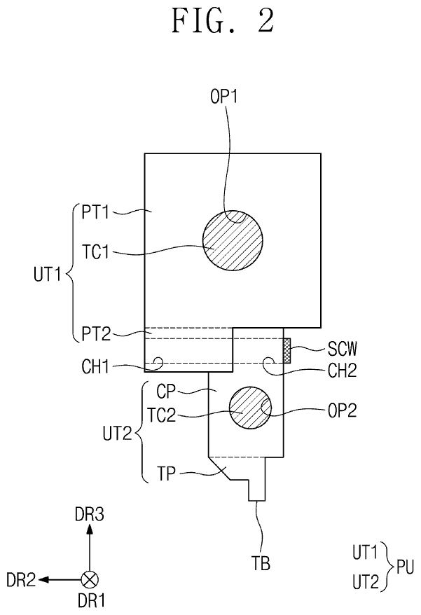

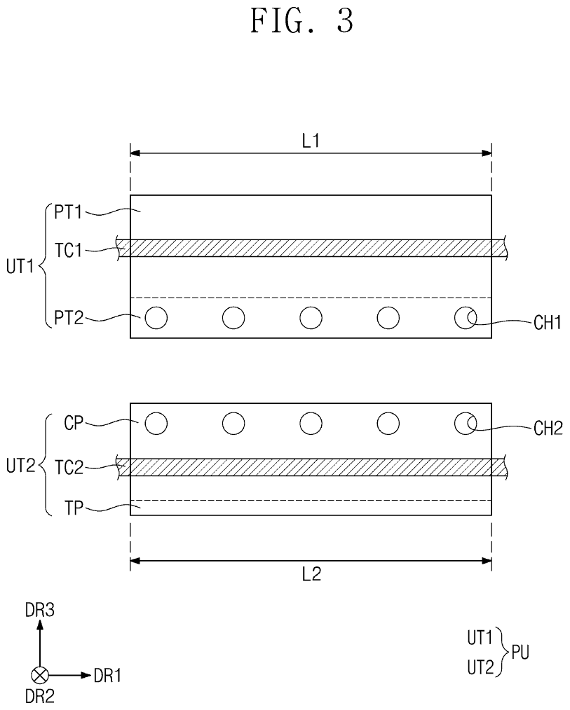

FIG. 2 is a side view of the press unit PU according to an embodiment of the present disclosure. FIG. 3 is a side view of the first unit UT1 and the second unit UT2 before the first and second units UT1 and UT2 are assembled with each other. FIG. 4 is a side view of the first unit UT1 and the second unit UT2 after the first and second units UT1 and UT2 are assembled with each other.

Hereinafter, the structure and function of the press unit PU will be described with reference to FIGS. 2 to 4.

Referring to FIG. 2, the press unit PU may include the first unit UT1 and the second unit UT2.

The first unit UT1 may include a first portion PT1, a second portion PT2, and a first temperature control part TC1. However, the first portion PT1 and the second portion PT2 are merely distinguished from each other for the convenience of explanation, and the first unit UT1 may have a continuous integral shape.

A first insertion opening OP1 may be defined through the first portion PT1. The first insertion opening OP1 may be an opening that penetrates through the first portion PT1 and extends in the first direction DR1. The first temperature control part TC1 may be disposed in the first insertion opening OP1. That is, the first temperature control part TC1 may be disposed inside the first insertion opening OP1.

As illustrated in FIG. 2, the first insertion opening OP1 has a circular shape when viewed in the first direction DR1. However, the shape of the first insertion opening OP1 should not be particularly limited as long as the first temperature control part TC1 is disposed in the first insertion opening OP1.

The second portion PT2 may be defined under the first portion PT1. As illustrated in FIG. 2, the second portion PT2 has a quadrangular shape when viewed in the first direction DR1, but the shape of the second portion PT2 should not be particularly limited.

First fastening holes CH1 described later may be defined through the second portion PT2. In the present embodiment, the first fastening holes CH1 may be openings that penetrates through the second portion PT2 of the first unit UT1 along the second direction DR2.

The first temperature control part TC1 may be disposed above the first fastening holes CH1, and the second temperature control part TC2 may be disposed below second fastening holes CH2. Accordingly, when viewed in the first direction DR1 or the second direction DR2, the first temperature control part TC1 may not overlap the first fastening holes CH1, and the second temperature control part TC2 may not overlap the second fastening holes CH2.

The first unit UT1 may include a first material having a first thermal expansion coefficient. As an example, the first material may include an extremely hard material, such as, for example, SKD11™ or tungsten carbide.

The second unit UT2 may be disposed under the first unit UT1 and may be in contact with the first unit UT1.

The second unit UT2 may include a fastening part CP, a tip part TP, and the second temperature control part TC2. However, the fastening part CP and the tip part TP are merely distinguished from each other for the convenience of explanation, and the second unit UT2 may have a continuous integral shape.

A second insertion opening OP2 may be defined through the fastening part CP. The second insertion opening OP2 may be an opening that penetrates through the fastening part CP and extends in the first direction DR1. The second temperature control part TC2 may be disposed in the second insertion opening OP2. That is, the second temperature control part TC2 may be disposed inside the second insertion opening OP2.

FIG. 2 illustrates that the second insertion opening OP2 has a circular shape when viewed from a side of the second insertion opening OP2 as a representative example, however, the shape of the second insertion opening OP2 should not be particularly limited as long as the second temperature control part TC2 is disposed in the second insertion opening OP2.

The tip part TP may be defined at a lower portion of the fastening part CP. The tip part TP may protrude from the second unit UT2 in a direction toward the stage STG (refer to FIG. 1). That is, the tip part TP may have a shape that protrudes downward from the fastening part CP.

A lower surface TB may be defined at a lower portion of the tip part TP. The lower surface TB may be directly in contact with a circuit board in the bonding process and may press the circuit board. Therefore, the lower surface TB may be flat to apply a uniform pressure to the circuit member.

The second unit UT2 may include a second material having a second thermal expansion coefficient. As an example, the second material may include an extremely hard material, such as, for example, SKD11™ or tungsten carbide.

Referring to FIG. 3, the first fastening holes CHI may be defined through the first unit UT1 and may be spaced apart from each other in the first direction DR1, and the second fastening holes CH2 may be defined through the second unit UT2 and may be spaced apart from each other in the first direction DR1.

A separation distance between the first fastening holes CH1 may be substantially the same as a separation distance between the second fastening holes CH2.

In the present embodiment, the first unit UT1 and the second unit UT2 may extend in the first direction DR1. A length in the first direction DR1 of the first unit UT1 may be referred to as a first length L1, and a length in the first direction DR1 of the second unit UT2 may be referred to as a second length L2.

In the press unit PU, the first length L1 may be substantially the same as the second length L2.

According to a conventional press unit, first and second units have different lengths in the first direction DR1 to compensate for a difference in thermal expansion amount between the first unit and the second unit in the first direction DR1.

However, according to the press unit PU of the present disclosure, the temperature of each of the first unit UT1 and the second unit UT2 may be set by taking into account the thermal expansion coefficient of the first unit UT1 and the second unit UT2, and thus, the first unit UT1 and the second unit UT2 may have substantially the same thermal expansion amount in the first direction DR1. Therefore, even though the first length L1 is the same as the second length L2, the press unit PU may be prevented from being deformed due to the difference in thermal expansion amount between the first unit UT1 and the second unit UT2.

However, the first length L1 and the second length L2 should not be particularly limited as long as the separation distance between the first fastening holes CH1 is the same as the separation distance between the second fastening holes CH2.

FIG. 4 illustrates the assembled state of the first unit UT1 and the second unit UT2 by the fastening members SCW.

The first fastening holes CHI may be defined through the second portion PT2 of the first unit UT1, and the second fastening holes CH2 (refer to FIG. 3) may be defined through the fastening part CP of the second unit UT2. The first unit UT1 and the second unit UT2 may be coupled with and fixed to each other by the fastening member SCW.

The first unit UT1 and the second unit UT2 may be coupled with each other by inserting the fastening members SCW into the first fastening holes CHI and the second fastening holes CH2 in a state where at least a portion of the second portion PT2 overlaps the fastening part CP.

Although not illustrated separately, the first temperature control part TC1 may include a first temperature sensor and a first heating member and may be connected to an external power source. As an example, the first heating member may be a resistive element, such as, for example, a first resistor heating wire. Accordingly, when a voltage is applied to the first temperature control part TC1, the first resistor heating wire may generate heat.

The heat generated from the first temperature control part TC1 may be transmitted to the first portion PT1 and the second portion PT2.

The first temperature sensor of the first temperature control part TC1 may measure the temperature of the first unit UT1.

When the temperature of the first unit UT1 is lower than a target temperature of the first unit UT1 used in the bonding process, the external power source may apply the voltage to the first resistor heating wire, and thus, the first resistor heating wire may generate the heat. In the present disclosure, the target temperature of the first unit UT1 used in the bonding process may be referred to as a first reference temperature.

The first temperature control part TC1 may increase the temperature of the first unit UT1 until the temperature of the first unit UT1 reaches the first reference temperature.

When the temperature of the first unit UT1 is equal to the first reference temperature, the first temperature control part TC1 may generate a small amount of heat to compensate for the heat emitted to the atmosphere by the first unit UT1, and thus, the temperature of the first unit UT1 may be maintained. That is, the first temperature control part TC1 may maintain the temperature of the first unit UT1 at the first reference temperature targeted for (e.g., required in) the bonding process.

Although not illustrated separately, the second temperature control part TC2 may include a second temperature sensor and a second heating member and may be connected to the external power source. The second heating member may be a resistive element, such as, for example, a second resistor heating wire.

The heat generated from the second temperature control part TC2 may be transmitted to the fastening part CP and the tip part TP.

The second temperature sensor of the second temperature control part TC2 may measure the temperature of the second unit UT2. In an example in which the temperature of the second unit UT2 is lower than a second reference temperature, the external power source may apply the voltage to the second resistor heating wire to generate the heat. That is, the second temperature control part TC2 may increase the temperature of the second unit UT2 to the second reference temperature targeted for (e.g., required in) the bonding process.

When the temperature of the second unit UT2 is equal to the second reference temperature, the temperature sensor of the second temperature control part TC2 may generate a small amount of heat to compensate for the heat emitted to the atmosphere by the second unit UT2, and thus, the temperature of the second unit UT2 may be maintained. That is, the second temperature control part TC2 may maintain the temperature of the second unit UT2 at the second reference temperature targeted for (e.g., required in) the bonding process. The first temperature control part TC1 and the second temperature control

part TC2 may adjust the temperature of the first unit UT1 and the temperature of the second unit UT2 to allow a length variation rate to be within a certain numerical range. In the present disclosure, the length variation rate may be defined as a value obtained by subtracting a value obtained by multiplying the second thermal expansion coefficient by a temperature variation amount of the second unit UT2 from a value obtained by multiplying the first thermal expansion coefficient by a temperature variation amount of the first unit UT1.

The first temperature control part TC1 and the second temperature control part TC2 may adjust the temperature of the first unit UT1 and the temperature of the second unit UT2 such that the value obtained by multiplying the first thermal expansion coefficient by the temperature variation amount of the first unit UT1 ranges from about 0.9 times to about 1.1 times of the value obtained by multiplying the second thermal expansion coefficient by the temperature variation amount of the second unit UT2. In the present disclosure, a temperature variation amount of a certain unit may mean a value obtained by subtracting a temperature of the certain unit before being adjusted by a temperature control part from a temperature of the certain unit after being adjusted by the temperature control part, when the temperature of the certain unit is adjusted by the temperature control part.

However, preferably, the first temperature control part TC1 and the second temperature control part TC2 may adjust the temperature of the first unit UT1 and the temperature of the second unit UT2, respectively, to allow the value obtained by multiplying the first thermal expansion coefficient by the temperature of the first unit UT1 to be equal to the value obtained by multiplying the second thermal expansion coefficient by the temperature of the second unit UT2.

Accordingly, the thermal expansion amount of the first unit UT1 may be the same as the thermal expansion amount of the second unit UT2 or may be different from the thermal expansion amount of the second unit UT2 by approximately 10%.

As the bonding apparatus BTA according to the present disclosure may allow the lower surface TB of the tip part TP to be flat using the first temperature control part TC1 and the second temperature control part TC2, bonding defects may be prevented from occurring.

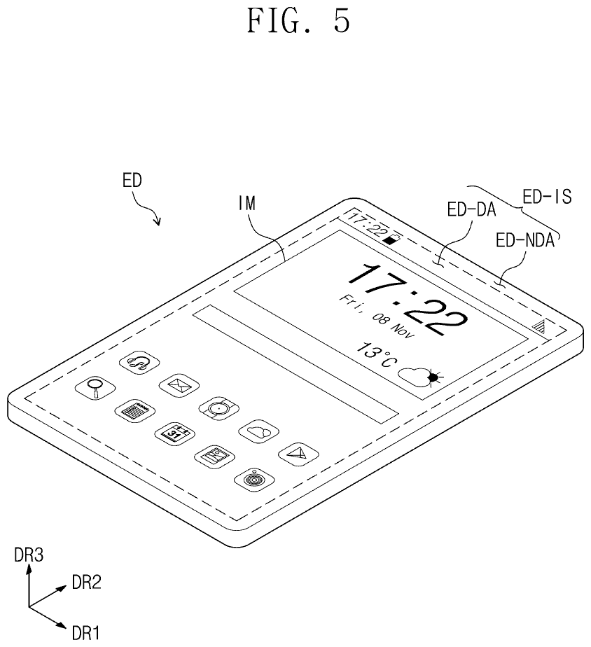

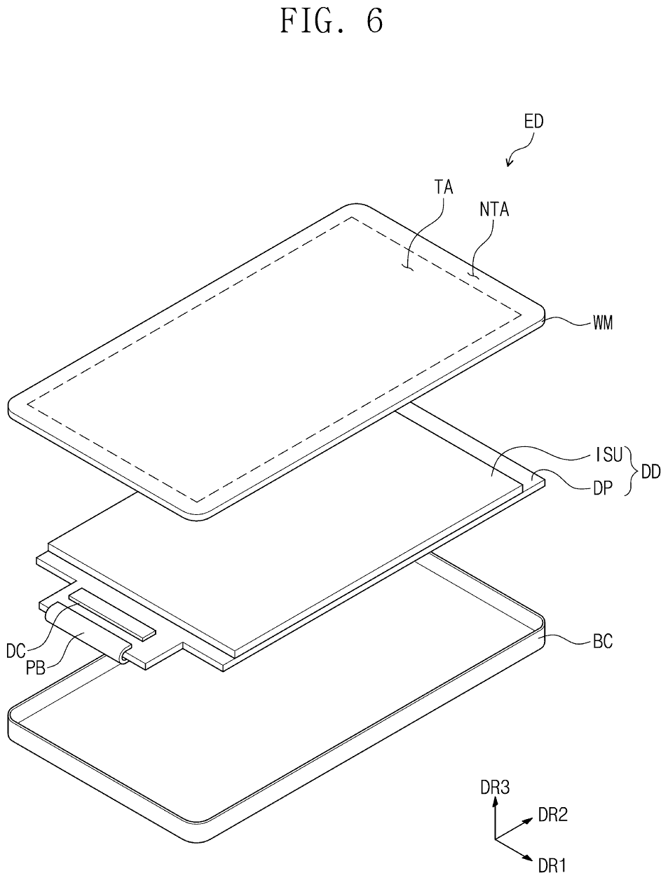

FIG. 5 is a perspective view of an electronic device ED including a display panel manufactured using the bonding apparatus illustrated in FIG. 1. FIG. 6 is an exploded perspective view of the electronic device ED illustrated in FIG. 5.

Referring to FIGS. 5 and 6, the electronic device ED may be activated in response to electrical signals. In the present embodiment, a smartphone is illustrated as a representative example of the electronic device ED. However, the present disclosure should not be limited thereto or thereby, and the electronic device ED may be applied to various electronic items, such as, for example, a personal computer, a notebook computer, a television set, a personal digital assistant, a car navigation unit, a game unit, a smartphone, a tablet computer, a camera, and the like.

The electronic device ED may display an image IM through a display surface ED-IS. FIG. 5 illustrates icon images as a representative example of the image IM. The display surface ED-IS may be substantially parallel to a plane defined by the first direction DR1 and the second direction DR2.

The display surface ED-IS may include a display area ED-DA through which the image IM is displayed and a non-display area ED-NDA adjacent to the display area ED-DA. The non-display area ED-NDA may be an area through which the image IM is not displayed. However, the present disclosure should not be limited thereto or thereby, and the non-display area ED-NDA may be defined adjacent to one side of the display area ED-DA or may be omitted.

Referring to FIG. 6, the electronic device ED may include a window WM, a display device DD, and an accommodation member BC.

The window WM may be disposed above the display device DD and may transmit the image IM provided from the display device DD to the outside of the electronic device ED. The window WM may include a transmission area TA and a non-transmission area NTA.

The window WM may include a base layer and functional layers disposed on the base layer. The functional layers may include a protective layer, an anti-fingerprint layer, and the like. The base layer of the window WM may include a glass, sapphire, or plastic material. The base layer of the window WM may include an optically transparent insulating material. For example, the base layer of the window WM may include a glass substrate or a plastic film or may include a glass substrate and a plastic film coupled to the glass substrate by an adhesive.

The transmission area TA may overlap the display area ED-DA illustrated in FIG. 5 and may have a shape corresponding to the shape of the display area ED-DA. The transmission area TA may transmit the image IM (refer to FIG. 5) displayed in the display device DD to the outside of the electronic device ED.

The non-transmission area NTA may overlap the non-display area ED-NDA illustrated in FIG. 5 and may have a shape corresponding to the shape of the non-display area ED-NDA. The non-transmission area NTA may have a relatively low light transmittance compared to light transmittance of the transmission area TA. The non-transmission area NTA may be defined by a bezel pattern disposed in a portion of the base layer of the window WM, and an area in which the bezel pattern is not disposed may be defined as the transmission area TA. However, the present disclosure should not be limited thereto or thereby, and the non-transmission area NTA may be omitted.

According to an embodiment, an anti-reflective layer may be disposed between the window WM and the display device DD. The anti-reflective member may reduce a reflectance of the display device DD with respect to the external light incident thereto from the outside of the display device DD. The anti-reflective layer may include color filters. The color filters may be arranged in a predetermined arrangement. As an example, the color filters may be arranged by taking into account light emission colors of pixels included in the display panel DP described later. In some aspects, the anti-reflective layer may further include a black matrix disposed adjacent to the color filters.

The display device DD may include the display panel DP and an input sensing unit ISU.

The display panel DP may be a liquid crystal display panel or a light emitting type display panel. As an example, the display panel DP may be the liquid crystal display panel including a liquid crystal element, an organic electroluminescence display panel including an organic electroluminescence element, or a quantum dot light emitting display panel including a quantum dot light emitting element, however, the present disclosure should not be limited thereto or thereby. Hereinafter, an organic light emitting display panel will be described as the display panel DP.

The input sensing unit ISU may be disposed on the display panel DP. The input sensing unit ISU may include one of a capacitive sensor, an optical sensor, an ultrasonic sensor, and an electromagnetic induction sensor. The input sensing unit ISU may be formed on the display panel DP through successive processes or may be attached to an upper portion of the display panel DP using an adhesive layer after being separately manufactured.

The display device DD may further include a driving chip DC and a circuit board PB, which are mounted on the display panel DP.

In the present embodiment, the circuit board PB may be a flexible circuit board. Hereinafter, the circuit board PB will be described as the flexible circuit board, and the flexible circuit board will be assigned with the same reference numerals as the circuit board PB. However, properties of the circuit board PB should not be limited thereto or thereby, and the circuit board PB may be rigid.

The flexible circuit board PB may electrically connect the display panel DP and a main circuit board.

The driving chip DC may be mounted on the display panel DP. The driving chip DC may be an integrated circuit provided in the form of a chip after being coupled to pads exposed on the display panel DP.

The driving chip DC may be connected to at least some of signal lines connected to the pixels. The driving chip DC may provide electrical signals to each of the pixels arranged in the display panel DP through the signal lines.

The driving chip DC may include driving elements to drive the pixels. As an example, the driving chip DC may include a data driving circuit that is connected to data lines DL (refer to FIG. 7) to apply a data signal to each of the data lines DL.

The driving chip DC may be connected to the circuit board PB.

In the present embodiment, the driving chip DC directly mounted on the display panel DP and the flexible circuit board PB may be referred to as a circuit member.

The circuit board PB may be bent such that a portion of the circuit board PB faces a rear surface of the display panel DP, however, the present disclosure should not be limited thereto or thereby. According to an embodiment, a portion of the display panel DP may be bent such that the driving chip DC faces the rear surface of the display device DD.

The accommodation member BC may accommodate the display device DD. The accommodation member BC may be coupled with the window WM and may define an exterior of the electronic device ED. The accommodation member BC may include a material with a relatively high rigidity and may absorb an external impact applied thereto from the outside. The accommodation member BC may include a plurality of accommodation portions coupled with each other.

The display device DD may further include a main board, electronic modules mounted on the main board, a camera module, a power supply module, etc., which are accommodated in the accommodation member BC.

FIG. 7 is a plan view of the display panel illustrated in FIG. 6.

Referring to FIG. 7, the display panel DP may include the pixels PX, a gate driving circuit GDC, a plurality of signal lines SGL, and a plurality of signal pads DP-PD.

The pixels PX may be arranged in a display area DP-DA. Each of the pixels PX may include a light emitting element and a pixel driving circuit connected to the light emitting element. In the present embodiment, the light emitting element may be an organic light emitting element.

The gate driving circuit GDC may be disposed in a non-display area DP-NDA of the display panel DP. The gate driving circuit GDC may sequentially output gate signals to gate lines GL. The gate driving circuit GDC may include a transistor formed through the same process, e.g., a low temperature polycrystalline silicon (LTPS) process, a low temperature polycrystalline oxide (LTPO) process, or a hybrid oxide and polycrystalline silicon (HOP) process, as a transistor of the pixel PX.

However, the driving circuit of the display panel DP should not be limited to the gate driving circuit GDC, and the display panel DP may further include another driving circuit to apply a light emission control signal to the pixels PX. As an example, the display panel DP may include a light emission driving circuit.

The signal lines SGL may be disposed in the display area DP-DA and the non-display area DP-NDA. The signal lines SGL may include the gate lines GL, the data lines DL, a power line PL, and a control signal line CSL. Each of the gate lines GL may be connected to a corresponding pixel PX among the pixels PX, and each of the data lines DL may be connected to a corresponding pixel PX among the pixels PX. The power line PL may be connected to the pixels PX. The control signal line CSL may provide control signals to the gate driving circuit GDC.

The signal pads DP-PD may be disposed in the non-display area DP-NDA. The signal pads DP-PD may include first pads PD1, second pads PD2, and third pads PD3.

The non-display area DP-NDA may include a first pad area PA1 and a second pad area PA2. The first pads PD1 and the second pads PD2 may be disposed in the first pad area PA1, and the driving chip DC may be disposed in the first pad area PA1. The third pads PD3 may be disposed in the second pad area PA2, and the circuit board PB may be disposed in the second pad area PA2.

The first pad area PA1 and the second pad area PA2 may be spaced apart from each other in second direction DR2.

The first pad area PA1 may include a first area B1 in which the first pads PD1 are disposed and a second area B2 in which the second pads PD2 are disposed. The first pads PD1 may be arranged in the first area B1 along the first direction DR1, and the second pads PD2 may be arranged in the second area B2 along the first direction DR1. Hereinafter, the area in which the first pads PD1 and the second pads PD2 are disposed may be referred to as the first pad area PA1, and the area in which the third pads PD3 are disposed may be referred to as the second pad area PA2.

The first pads PD1, the second pads PD2, and the third pads PD3 may be exposed to the outside in the non-display area DP-NDA of the display panel DP, and this will be described in detail later.

In the present embodiment, the first pads PD1 may be arranged in one row in the first area B1. The second pads PD2 may be arranged in one row in the second area B2. However, the number of rows in which the first and second pads PD1 and PD2 are arranged should not be limited thereto or thereby. As an example, each of the first and second pads PD1 and PD2 may be arranged in two or more rows in a corresponding area of the first and second areas B1 and B2.

Referring to FIG. 7, the second area B2 may be spaced apart from the first area B1 in the second direction DR2. The second pads PD2 arranged in the second area B2 may be connected to the third pads PD3 arranged in the second pad area PA2 via connection signal lines S-CL in a one-to-one correspondence.

The circuit board PB may include substrate bump electrodes PB-BP. The substrate bump electrodes PB-BP may be arranged in the first direction DR1. The substrate bump electrodes PB-BP of the circuit board PB may be connected to the third pads PD3 of the second pad area PA2.

FIG. 8 is an enlarged perspective view of a portion of the display panel DP illustrated in FIG. 6.

FIG. 8 is an enlarged perspective view of the first and second pad areas PA1 and PA2 of the display device DD according to an embodiment of the present disclosure. As an example, in FIG. 8, the driving chip DC and the circuit board PB are illustrated disassembled from the display panel DP. The arrangement and connection relationships between the first pad area PA1 and the second pad area PA2 are described with reference to FIG. 7, and repeated descriptions of the same are omitted for brevity.

Referring to FIG. 8, the driving chip DC may include a driving bump electrode DC-BP. The driving bump electrode DC-BP may include first bumps BP1 connected to the first pads PD1 in a one-to-one correspondence and second bumps BP2 connected to the second pads PD2 in a one-to-one correspondence.

A first film CF1 may be disposed between the driving chip DC and the first pad area PA1.

The first film CF1 may include a synthetic resin with an adhesive property and an anisotropic conductive film (ACF) including conductive balls, however, the present disclosure should not be limited thereto or thereby. As an example, the first film CF1 may include a non-conductive film (NCF).

When the driving chip DC disposed on the first film CF1 in the first pad area PA1 is pressed, the driving bump electrode DC-BP may be electrically connected to the first and second pads PD1 and PD2.

The circuit board PB may include the substrate bump electrodes PB-BP mounted therein. The circuit board PB may provide an image signal, a driving voltage, and other control signals to the driving chip DC.

The substrate bump electrodes PB-BP may be disposed on a lower surface PB-DS of the circuit board PB. The substrate bump electrodes PB-BP may be connected to the third pads PD3 in a one-to-one correspondence. A second film CF2 may be disposed between the circuit board PB and the second pad area PA2. Each of the substrate bump electrodes PB-BP may be connected to the third pad PD3 arranged in the first direction DR1 through the connection signal line S-CL (refer to FIG. 7).

The second film CF2 may include a synthetic resin with an adhesive property and an anisotropic conductive film (ACF) including conductive balls, however, the present disclosure should not be limited thereto or thereby. As an example, the second film CF2 may include a non-conductive film (NCF).

The driving chip DC may receive first signals through the second pads PD2 and the second bumps BP2. The driving chip DC may provide second signals generated based on the first signals to the first pads PD1 through the first bumps BP1. As an example, when the driving chip DC includes the data driving circuit, the second signals may be generated based on the first signals through the data driving circuit.

The first signals may be image signals that are digital signals applied thereto from the outside, and the second signals may be data signals that are analog signals. The driving chip DC may generate analog voltages corresponding to grayscale values of the image signals. The data signals may be applied to the pixels through the data lines DL (refer to FIG. 7).

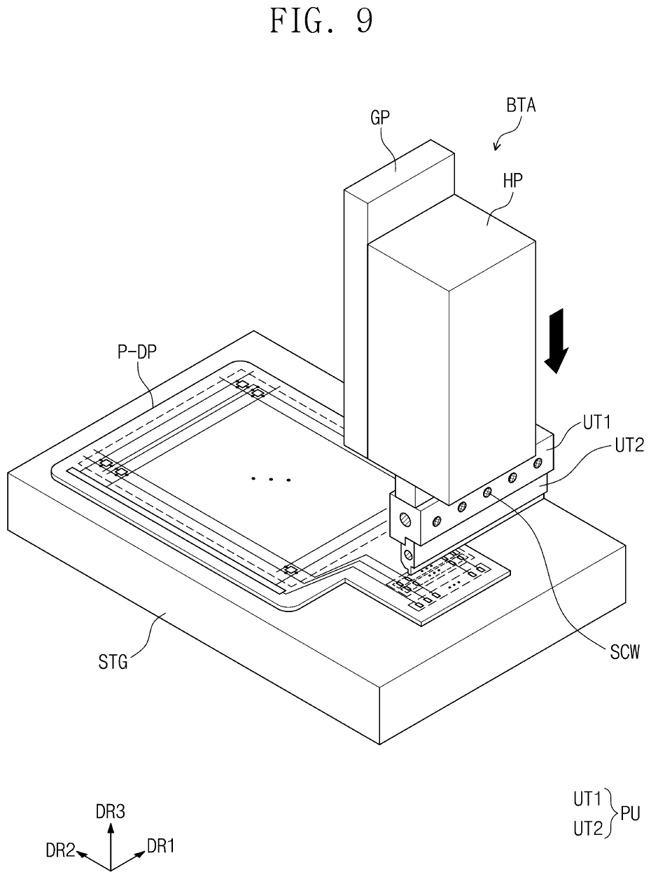

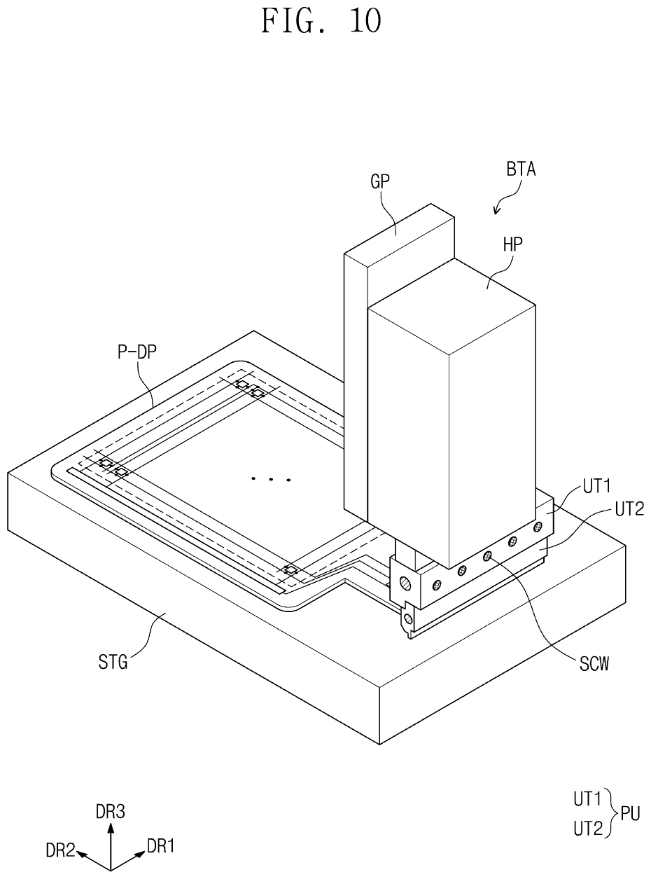

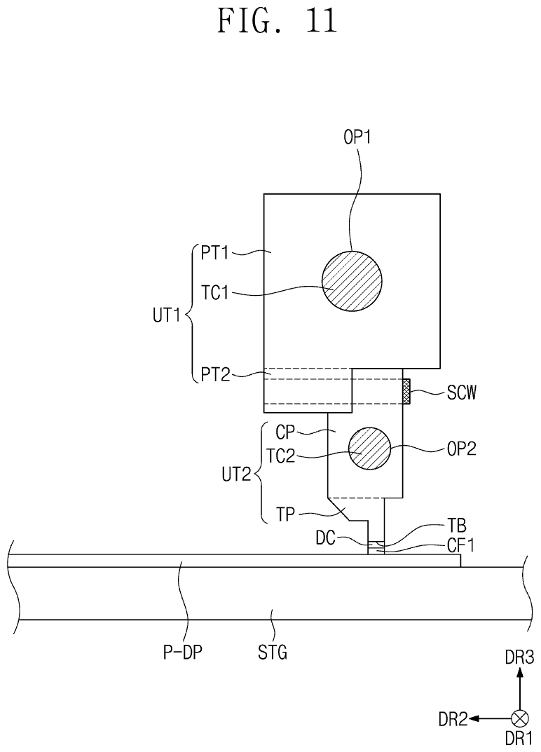

FIGS. 9 and 10 are perspective views of the bonding apparatus BTA according to an embodiment of the present disclosure. FIG. 11 is a side view of the bonding apparatus BTA illustrated in FIG. 10.

Hereinafter, a bonding process of the preliminary display panel P-DP and the driving chip DC will be described as a representative example of a bonding process of the preliminary display panel P-DP and the circuit member. The bonding process and bonding structure of the preliminary display panel P-DP and the driving chip DC may be applied to the bonding process and bonding structure of the preliminary display panel P-DP and other circuit members such as, for example, the flexible circuit board PB (refer to FIG. 8).

Referring to FIG. 9, the preliminary display panel P-DP and the driving chip DC (refer to FIG. 8) may be disposed on the stage STG. In the present disclosure, the preliminary display panel P-DP may refer to the display panel DP (refer to FIG. 6) in a state before the display panel DP is completed in the manufacturing process of the display device. For the sake of explanation, the circuit member disposed between the preliminary display panel P-DP and the press unit PU is omitted in FIG. 9.

The inside of the suction holes VFH (refer to FIG. 1) defined through the stage upper surface SU is converted to the vacuum state, and thus, the preliminary display panel P-DP may be fixed to the upper surface of the stage STG.

After the preliminary display panel P-DP is fixed to the stage STG, the head part HP may move in the third direction DR3 along one side of the guide part GP. As the head part HP moves in the third direction DR3, the press unit PU connected to the head part HP may also move in the third direction DR3. Accordingly, the tip part TP included in the press unit PU may move in the third direction DR3.

FIG. 10 illustrates the state in which the head part HP descends and the tip part TP (refer to FIG. 11) included in the press unit PU presses the driving chip DC as a representative example.

FIG. 11 is a view illustrating the state in which the tip part TP included in the press unit PU presses the driving chip DC when viewed in the first direction DR1. In FIG. 11, for the convenience of explanation, the head part HP (refer to FIG. 1), the guide part GP (refer to FIG. 1), and the connection part CST (refer to FIG. 1), which are included in the bonding apparatus BTA (refer to FIG. 1), are omitted.

Referring to FIG. 11, when the press unit PU presses the driving chip DC, the heat generated from the first temperature control part TC1 may be transferred to the driving chip DC through the fastening part CP and the tip part TP of the second unit UT2.

In some aspects, the heat generated from the second temperature control part TC2 may be transferred to the driving chip DC through the fastening part CP and the tip part TP of the second unit UT2.

The first film CF1 may receive the heat through the driving chip DC that is in contact with the tip part TP and may be cured. Therefore, the driving chip DC and the preliminary display panel P-DP may be bonded to each other.

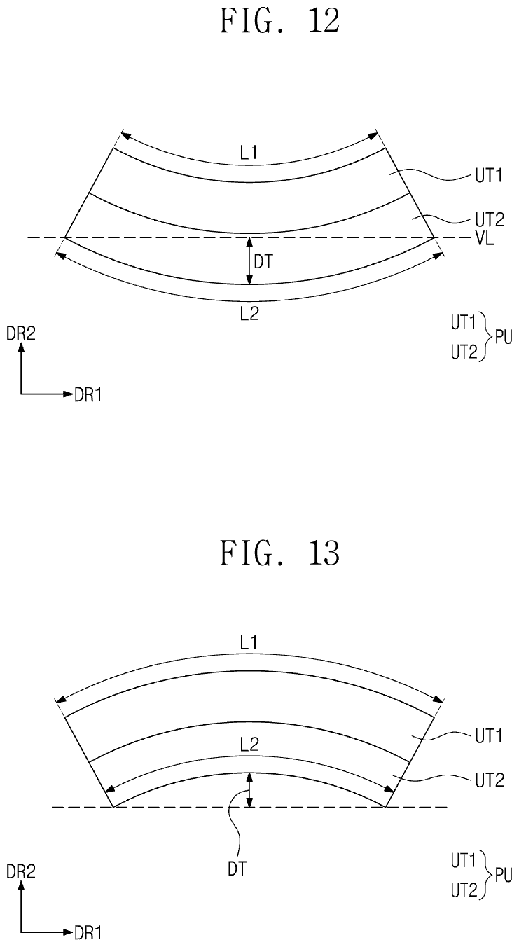

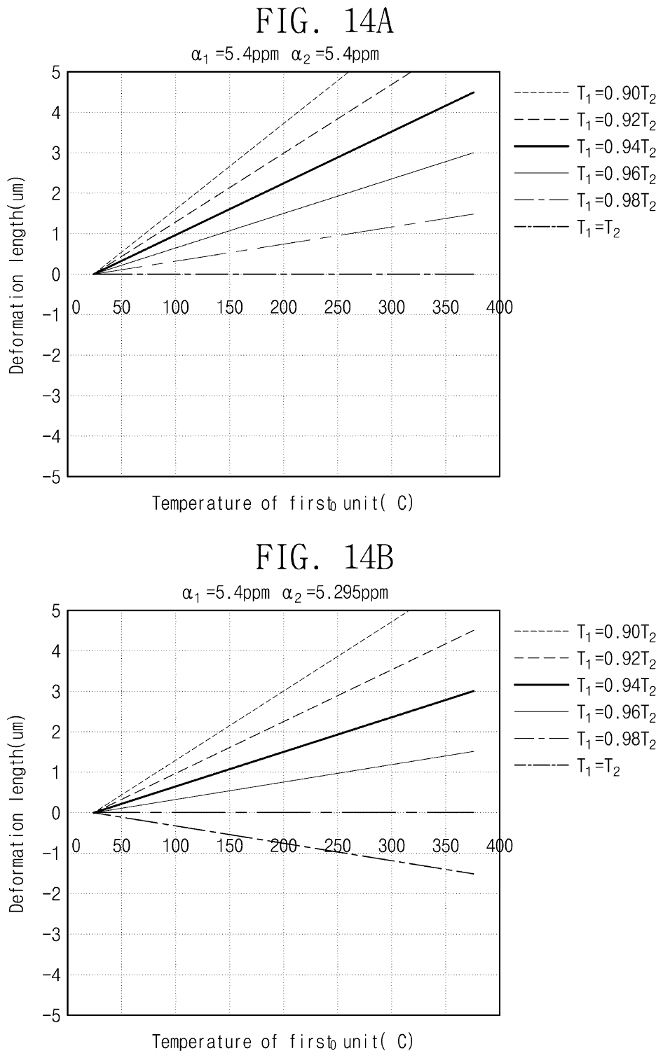

FIGS. 12 and 13 are views illustrating a deformation length of the press unit PU.

For the convenience of explanation, the first and second fastening holes CH1 and CH2 (refer to FIG. 3) and the first and second temperature parts TC1 and TC2 (refer to FIG. 4) are omitted in FIGS. 12 and 13.

FIG. 12 illustrates the press unit PU in which the thermal expansion amount of the first unit UT1 is smaller than the thermal expansion amount of the second unit UT2. That is, in the press unit PU illustrated in FIG. 12, the value obtained by multiplying the thermal expansion coefficient of the first unit UT1 by the temperature variation amount of the first unit UT1 may be smaller than the value obtained by multiplying the thermal expansion coefficient of the second unit UT2 by the temperature variation amount of the second unit UT2.

When the thermal expansion amount of the first unit UT1 is smaller than the thermal expansion amount of the second unit UT2, the first length L1 may be smaller than the second length L2. Accordingly, the press unit PU may be deformed to be convex in a direction from the first unit UT1 to the second unit UT2.

In this case, a length from a center of an imaginary straight line VL connecting one end and the other end of the lower surface TB (refer to FIG. 11) of the second unit UT2 to the lower surface TB of the second unit UT2 may be referred to as the deformation length DT.

When the press unit PU is deformed to be convex in the direction from the first unit UT1 to the second unit UT2, the deformation length DT may be defined to have a ‘positive value’.

FIG. 13 illustrates the press unit PU in which the thermal expansion amount of the first unit UT1 is greater than the thermal expansion amount of the second unit UT2. That is, in the press unit PU illustrated in FIG. 13, the value obtained by multiplying the thermal expansion coefficient of the first unit UT1 by the temperature variation amount of the first unit UT1 may be greater than the value obtained by multiplying the thermal expansion coefficient of the second unit UT2 by the temperature variation amount of the second unit UT2.

When the thermal expansion amount of the first unit UT1 is greater than the thermal expansion amount of the second unit UT2, the first length L1 may be longer than the second length L2. Accordingly, the press unit PU may be deformed to be convex in a direction from the second unit UT2 to the first unit UT1.

When the press unit PU is deformed to be convex in the direction from the second unit UT2 to the first unit UT1, the deformation length DT may be defined to have a ‘negative value’.

The bonding apparatus according to the present disclosure may adjust the temperature of the first unit UT1 and the temperature of the second unit UT2 to reduce an absolute value of the deformation length DT. In some aspects, the method of manufacturing the display device may include setting the temperature of the first unit UT1 and the temperature of the second unit UT2 according to a reference temperature ratio by taking into account the first thermal expansion coefficient of the first unit UT1 and the thermal expansion coefficient of the second unit UT2. According to one or more embodiments of the present disclosure, the method of manufacturing the display device may include appropriately selecting the first thermal expansion coefficient of the first unit UT1 and the second thermal expansion coefficient of the second unit UT2 in consideration of the reference temperature ratio used in the bonding process.

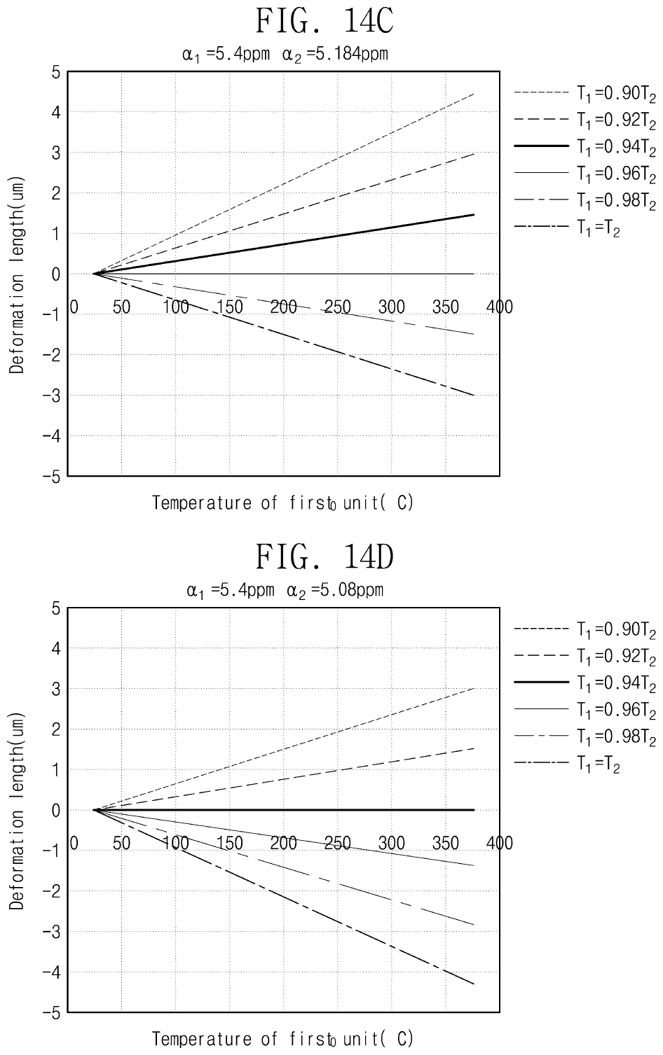

FIGS. 14A to 14F are graphs illustrating the deformation length according to the change in the temperature and the thermal expansion coefficient of the first and second units.

Hereinafter, a method of setting the reference temperature ratio that minimizes the deformation length DT (refer to FIG. 13) by adjusting the temperature and the thermal expansion coefficient of the first unit UT1 (refer to FIG. 1) and the second unit UT2 (refer to FIG. 1) will be described with reference to specific embodiments. In the present disclosure, the reference temperature ratio may be defined as a ratio of the first reference temperature to the second reference temperature.

In some embodiments, embodiments described herein are merely examples to aid understanding of the present disclosure, and the scope of the present disclosure should not be limited thereto or thereby.

FIG. 14A illustrates an embodiment in which the thermal expansion coefficient of the first unit UT1 (refer to FIG. 1) is about 5.4 ppm and the thermal expansion coefficient of the second unit UT2 (refer to FIG. 1) is about 5.4 ppm.

The temperature of the first unit UT1 included in each test example is set to about 0.9 times, about 0.92 times, about 0.94 times, about 0.96 times, about 0.98 times, or about 1 times the temperature of the second unit UT2.

When the temperature of the first unit UT1 (refer to FIG. 1) and the temperature of the second unit UT2 (refer to FIG. 1) are in a ratio of 1:1, the deformation length is about zero (0) in all temperatures tested.

That is, since the first unit UT1 (refer to FIG. 1) and the second unit UT2 (refer to FIG. 1) have the same thermal expansion coefficient and the temperature of the first unit UT1 is set to be the same as the temperature of the second unit UT2, the first unit UT1 and the second unit UT2 may have the same thermal expansion amount.

Accordingly, when the thermal expansion coefficient of each of the first unit UT1 (refer to FIG. 1) and the second unit UT2 (refer to FIG. 1) is about 5.4 ppm and the reference temperature ratio of the first unit UT1 to the second unit UT2 is 1:1, the deformation length DT (refer to FIG. 13) may be minimized in all processing temperatures.

FIG. 14B illustrates an embodiment in which the thermal expansion coefficient of the first unit UT1 (refer to FIG. 1) is about 5.4 ppm and the thermal expansion coefficient of the second unit UT2 (refer to FIG. 1) is about 5.295 ppm.

Referring to FIG. 14B, the temperature of the first unit UT1 included in each test example is set to about 0.9 times, about 0.92 times, about 0.94 times, about 0.96 times, about 0.98 times, or about 1 times the temperature of the second unit UT2.

When the temperature of the first unit UT1 (refer to FIG. 1) and the temperature of the second unit UT2 (refer to FIG. 1) are in a ratio of 0.98:1, the deformation length is about zero (0) in all temperatures tested.

Accordingly, when the thermal expansion coefficient of the first unit UT1 (refer to FIG. 1) and the thermal expansion coefficient of the second unit UT2 (refer to FIG. 1) are about 5.4 ppm and about 5.295 ppm, respectively, and the reference temperature ratio of the first unit UT1 to the second unit UT2 is 0.98:1, the deformation length DT (refer to FIG. 13) may be minimized in all processing temperatures.

FIG. 14C illustrates an embodiment in which the thermal expansion coefficient of the first unit UT1 (refer to FIG. 1) is about 5.4 ppm and the thermal expansion coefficient of the second unit UT2 (refer to FIG. 1) is about 5.184 ppm.

Referring to FIG. 14C, the temperature of the first unit UT1 included in each test example is set to about 0.9 times, about 0.92 times, about 0.94 times, about 0.96 times, about 0.98 times, or about 1 times the temperature of the second unit UT2.

When the temperature of the first unit UT1 (refer to FIG. 1) and the temperature of the second unit UT2 (refer to FIG. 1) are in a ratio of 0.96:1, the deformation length is about zero (0) in all temperatures tested.

Accordingly, when the thermal expansion coefficient of the first unit UT1 (refer to FIG. 1) and the thermal expansion coefficient of the second unit UT2 (refer to FIG. 1) are about 5.4 ppm and about 5.184 ppm, respectively, and the reference temperature ratio of the first unit UT1 to the second unit UT2 is 0.96:1, the deformation length DT (refer to FIG. 13) may be minimized in all processing temperatures.

FIG. 14D illustrates an embodiment in which the thermal expansion coefficient of the first unit UT1 (refer to FIG. 1) is about 5.4 ppm and the thermal expansion coefficient of the second unit UT2 (refer to FIG. 1) is about 5.08 ppm.

Referring to FIG. 14D, the temperature of the first unit UT1 included in each test example is set to about 0.9 times, about 0.92 times, about 0.94 times, about 0.96 times, about 0.98 times, or about 1 times the temperature of the second unit UT2.

When the temperature of the first unit UT1 (refer to FIG. 1) and the temperature of the second unit UT2 (refer to FIG. 1) are in a ratio of 0.94:1, the deformation length is about zero (0) in all temperatures tested.

Accordingly, when the thermal expansion coefficient of the first unit UT1 (refer to FIG. 1) and the thermal expansion coefficient of the second unit UT2 (refer to FIG. 1) are about 5.4 ppm and about 5.08 ppm, respectively, and the reference temperature ratio of the first unit UT1 to the second unit UT2 is 0.94:1, the deformation length DT (refer to FIG. 13) may be minimized in all processing temperatures.

FIG. 14E illustrates an embodiment in which the thermal expansion coefficient of the first unit UT1 (refer to FIG. 1) is about 5.4 ppm and the thermal expansion coefficient of the second unit UT2 (refer to FIG. 1) is about 4.97 ppm.

Referring to FIG. 14E, the temperature of the second unit UT2 (refer to FIG. 1), the temperature of the first unit UT1 included in each test example is set to about 0.9 times, about 0.92 times, about 0.94 times, about 0.96 times, about 0.98 times, or about 1 times the temperature of the second unit UT2.

When the temperature of the first unit UT1 (refer to FIG. 1) and the temperature of the second unit UT2 (refer to FIG. 1) are in a ratio of 0.92:1, the deformation length is about zero (0) in all temperatures tested.

Accordingly, when the thermal expansion coefficient of the first unit UT1 (refer to FIG. 1) and the thermal expansion coefficient of the second unit UT2 (refer to FIG. 1) are about 5.4 ppm and about 4.97 ppm, respectively, and the reference temperature ratio of the first unit UT1 to the second unit UT2 is 0.92:1, the deformation length DT (refer to FIG. 13) may be minimized in all processing temperatures.

FIG. 14F illustrates an embodiment in which the thermal expansion coefficient of the first unit UT1 (refer to FIG. 1) is about 5.4 ppm and the thermal expansion coefficient of the second unit UT2 (refer to FIG. 1) is about 4.86 ppm.

Referring to FIG. 14F, the temperature of the first unit UT1 included in each test example is set to about 0.9 times, about 0.92 times, about 0.94 times, about 0.96 times, about 0.98 times, or about 1 times the temperature of the second unit UT2.

When the temperature of the first unit UT1 (refer to FIG. 1) and the temperature of the second unit UT2 (refer to FIG. 1) are in a ratio of 0.90:1, the deformation length is about zero (0) in all temperatures tested.

Accordingly, when the thermal expansion coefficient of the first unit UT1 (refer to FIG. 1) and the thermal expansion coefficient of the second unit UT2 (refer to FIG.

1) are about 5.4 ppm and about 4.86 ppm, respectively, and the reference temperature ratio of the first unit UT1 to the second unit UT2 is 0.90:1, the deformation length DT (refer to FIG. 13) may be minimized in all processing temperatures.

As described herein, the bonding apparatus according to the present disclosure may determine the thermal expansion coefficient of each of the first unit UT1 and the second unit UT2 in consideration of the material of each of the first unit UT1 (refer to FIG. 1) and the second unit UT2 (refer to FIG. 1) and may maintain the reference temperature ratio of the first unit UT1 and the second unit UT2 using the first temperature control part TC1 and the second temperature control part TC2, which may reduce the difference in thermal expansion amount between the first unit UT1 and the second unit UT2.

In accordance with one or more embodiments of the present disclosure with respect to the bonding apparatus, the deformation length DT may be minimized within the range of the processing temperature, and the press unit PU (refer to FIG. 1) may have the flat lower surface TB (refer to FIG. 2).

The method of manufacturing the display device may include setting the reference temperature ratio such that the first reference temperature and the second reference temperature are included within the range of a target processing temperature, and embodiments of the present disclosure may include selectively combining the first unit UT1 (refer to FIG. 1) and the second unit UT2 (refer to FIG. 1) with each other by taking into account the target thermal expansion coefficient.

Accordingly, the bonding apparatus BTA (refer to FIG. 1) according to the present disclosure may prevent thermal deformation of the first unit UT1 and the second unit UT2. Therefore, the lower surface TB (refer to FIG. 2) of the second unit UT2 (refer to FIG. 1) may be flat in the bonding process, and thus, the pressure may be uniformly applied to the entire area of the circuit member.

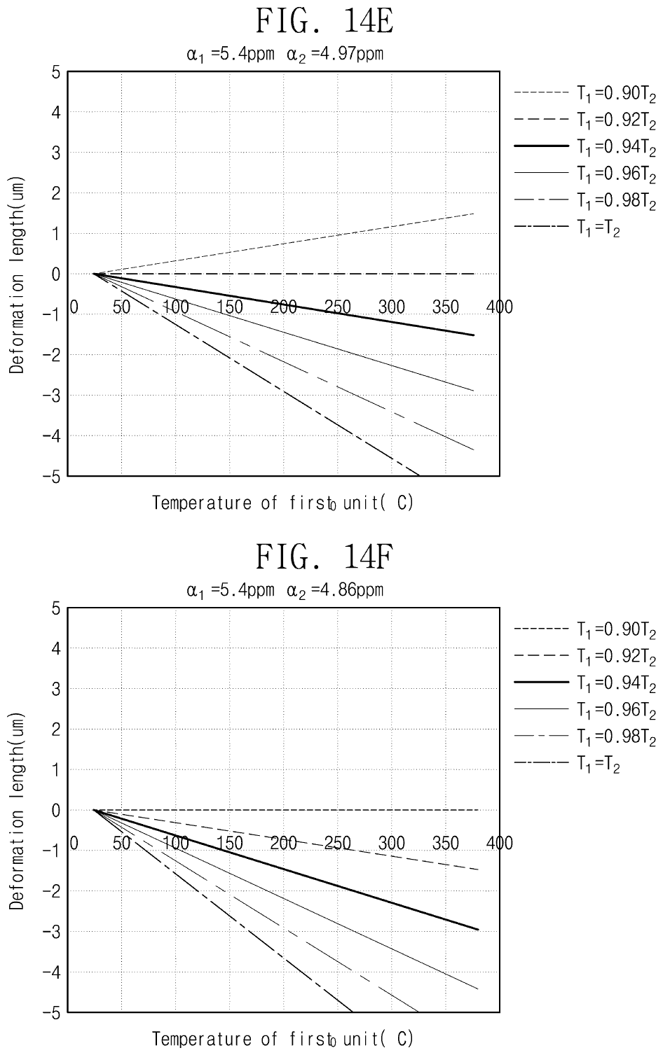

FIGS. 15 to 17 are flowcharts illustrating the method of manufacturing the display device according to an embodiment of the present disclosure.

Hereinafter, the method of manufacturing the display device, including setting the appropriate reference temperature ratio by taking into account the thermal expansion coefficients of the first unit UT1 (refer to FIG. 1) and the second unit UT2 (refer to FIG. 1) and pressing the circuit member using the press unit PU (refer to FIG. 1) after the first unit UT1 and the second unit UT2 reach the first reference temperature and the second reference temperature, respectively, will be described with reference to FIGS. 15 to 17. Referring to FIG. 15, the method of manufacturing the display device may include aligning the circuit member on the preliminary display panel including the pads on the stage (S10), placing the press unit, which includes the first unit including the first temperature control part and the second unit including the second temperature control part and coupled with the first unit under the first unit, on the circuit member (S20), and bonding the circuit member and the pads by pressing (applying pressure) using the press unit (S30).

In the bonding operation (S30), the tip part TP (refer to FIG. 11) may be in contact with the driving chip DC (refer to FIG. 11) and may transfer the heat from the second unit UT2 (refer to FIG. 11) to the driving chip DC.

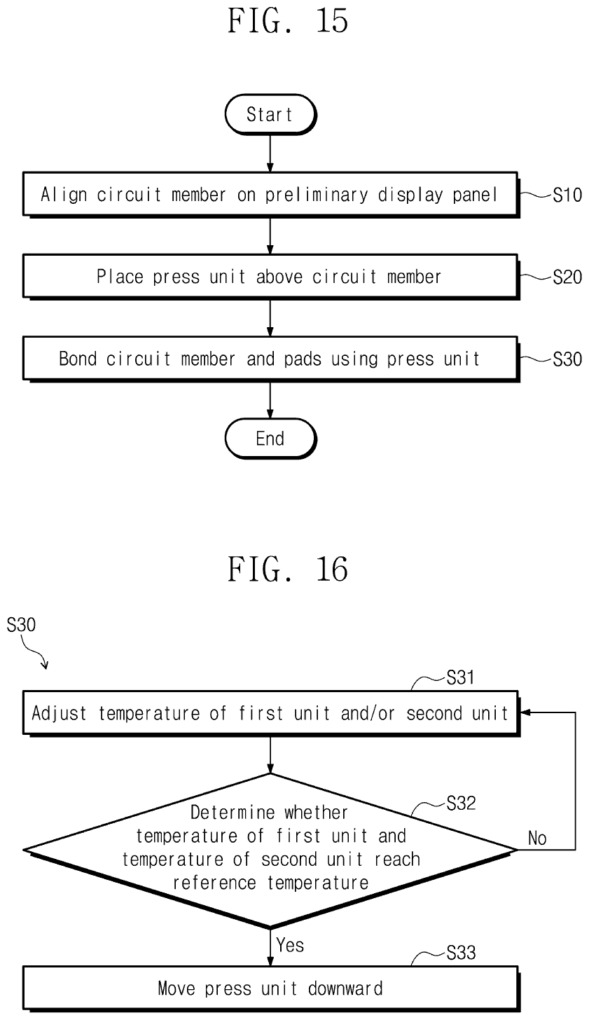

Referring to FIG. 16, the bonding operation (S30) may include adjusting the temperature of the first unit and the temperature of the second unit (S31) using the first temperature control part and the second temperature control part, respectively, determining whether the temperature of the first unit and the temperature of the second unit each reach a respective reference temperature (S32), and based on determining the temperature of the first unit and the temperature of the second unit are equal to (have each reached) the respective reference temperatures, moving the press unit downward (S33).

In determining whether the temperature of the first unit and the temperature of the second unit have each reached the respective reference temperature (S32), based on determining the temperature of the first unit and the temperature of the second unit are equal to the respective reference temperatures (when each of the first unit and the second unit reaches the respective reference temperature), the bonding operation (S30) may include proceeding with moving the press unit downward (S33), and when the temperature of either of the first unit and the second unit does not reach the respective reference temperature, the bonding operation (S30) may include proceeding with adjusting (S31) the temperature of the unit (e.g., first unit UT1, second unit UT2) not meeting the respective reference temperature. That is, for example, the bonding operation S30) may include proceeding with adjusting the temperature of the first unit UT1 and/or the temperature of the second unit UT2 (S31).

In some examples, the adjusting of the temperature of the first unit and/or the temperature of the second unit (S31) may include adjusting the temperature of the first unit and/or the temperature of the second unit in association with obtaining or maintaining the ratio (e.g., a first ratio) of the temperature of the second unit UT2 to the temperature of the first unit UT1 such that the first ratio ranges from about 0.9 times to about 1.1 times of the ratio (e.g., a second ratio) of the first thermal expansion coefficient to the second thermal expansion coefficient. In an example, the adjusting of the temperature of the first unit and/or the temperature of the second unit (S31) may include maintaining the ratios such that the ratio of the temperature of the second unit UT2 to the temperature of the first unit UT1 is substantially the same as the ratio of the first thermal expansion coefficient to the second thermal expansion coefficient.

The adjusting of the temperature of the first and second units (S31) may include supplying a current to each of the first resistor heating wire and the second resistor heating wire.

Additionally, or alternatively, the method and operations described herein may be based on whether the temperature of the first unit and/or the temperature of the second unit reaches a respective reference temperature, such that a target ratio of the temperature of the second unit UT2 to the temperature of the first unit UT1 is obtained or maintained. For example, in association with the ratio, some embodiments may include adjusting the temperature of the second unit UT2 while maintaining the temperature of the first unit UT1 to obtain the target ratio. In another example, some embodiments may include adjusting the temperature of the first unit UT1 while maintaining the temperature of the second unit UT2 to obtain the target ratio. Accordingly, in some example embodiments, the bonding operation (S30) may include determining whether the ratio satisfies a target ratio, in place of or in addition to the operations described with reference to S32.

The method of manufacturing the display device may include adjusting the temperature of the first unit UT1 (refer to FIG. 1) and the temperature of the second unit UT2 (refer to FIG. 1) in association with maintaining the reference temperature ratio when the materials of the first unit UT1 (refer to FIG. 1) and the second unit UT2 (refer to FIG. 1) are determined. Accordingly, the bonding pressure may be uniformly applied to the circuit member in the bonding process.

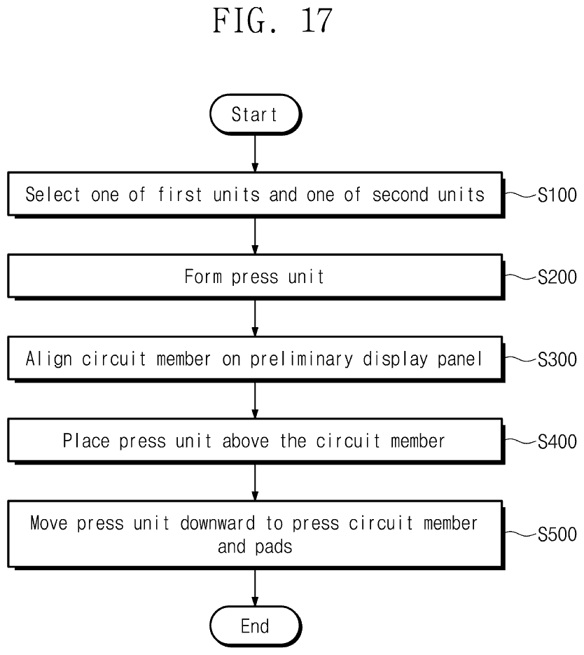

Referring to FIG. 17, the method of manufacturing the display device may include selecting one of multiple first units including the first temperature control part and selecting one of multiple second units including the second temperature control part (S100), forming the press unit including the selected first unit and the selected second unit coupled with a lower portion of the selected first unit (S200), aligning the circuit member on the preliminary display panel including the pads on the stage (S300), placing the press unit on the circuit member (S400), and moving the press unit downward to press the circuit member to be bonded to the pads (S500).

In the bonding of the circuit member (S500), the method may include maintaining the selected first unit UT1 at the first reference temperature by the first temperature control part TC1, and the method may include maintaining the selected second unit UT2 at the second reference temperature by the second temperature control part TC2.

Although not illustrated separately in the drawing, the forming of the press unit (S200) may include placing the second unit UT2 under the first unit UT1 and inserting the fastening members into the first fastening holes defined through the first unit UT1 and spaced apart from each other in the first direction and the second fastening holes defined through the second unit UT2 and spaced apart from each other in the first direction.

In accordance with one or more embodiments of the present disclosure, the method of manufacturing the display device may support providing the press unit PU (refer to FIG. 1) designed in consideration of the thermal expansion coefficient through the selecting of the first and second units (S100). Accordingly, when a certain processing temperature is desired for the bonding process, the method may include adjusting the thermal expansion coefficients of the first unit UT1 (refer to FIG. 1) and the second unit UT2 (refer to FIG. 1) to maintain the reference temperature ratio and/or certain processing temperature. Therefore, the method of manufacturing the display device as described herein may support uniformly applying the bonding pressure to the circuit member in the bonding process.

That is, the method of manufacturing the display device may prevent thermal deformation of the first unit UT1 and the second unit UT2, which may prevent or reduce costs associated with replacing the first unit UT1 (refer to FIG. 1) or the second unit UT2 (refer to FIG. 1) for cases of deformation. Thus, a manufacturing efficiency of the display device may increase.

In the descriptions of the flowcharts and operations provided herein, the operations may be performed in a different order than the order shown, or the operations may be performed in different orders or at different times. Certain operations may also be left out of the flowcharts, one or more operations may be repeated, or other operations may be added to the flowcharts.

Although the embodiments of the present disclosure have been described, it is understood that the present disclosure should not be limited to the example embodiments but various changes and modifications can be made by one ordinary skilled in the art within the spirit and scope of the present disclosure as hereinafter claimed. Therefore, the disclosed subject matter should not be limited to any single embodiment described herein, and the scope of the embodiments of the present disclosure shall be determined according to the attached claims.

What is claimed is:

1. A bonding apparatus comprising:
a first unit comprising:
a first temperature control part; and
first fastening holes defined through the first unit and spaced apart from each other in a first direction,
wherein the first unit has a first thermal expansion coefficient;
a second unit disposed under the first unit and being in contact with the first unit, the second unit comprising:
a second temperature control part; and
second fastening holes defined through the second unit and spaced apart from each other in the first direction,
wherein the second unit has a second thermal expansion coefficient;
fastening members each being inserted into a corresponding first fastening hole among the first fastening holes and a corresponding second fastening hole among the second fastening holes, wherein the corresponding second fastening hole is aligned with the corresponding first fastening hole in the first direction; and
a stage disposed under the second unit.

2. The bonding apparatus of claim 1, wherein the first temperature control part and the second temperature control part are configured to adjust a temperature of the first unit and a temperature of the second unit, respectively, based on a relationship between a value obtained by multiplying the first thermal expansion coefficient by a temperature variation amount of the first unit and a value obtained by multiplying the second thermal expansion coefficient by a temperature variation amount of the second unit.

3. The bonding apparatus of claim 1, wherein the first temperature control part and the second temperature control part are configured to adjust a temperature of the first unit and a temperature of the second unit, respectively, such that a value obtained by multiplying the first thermal expansion coefficient by a temperature variation amount of the first unit ranges from about 0.9 times to about 1.1 times of a value obtained by multiplying the second thermal expansion coefficient by a temperature variation amount of the second unit.

4. The bonding apparatus of claim 1, wherein:
the first temperature control part is disposed above the first fastening holes; and
the second temperature control part is disposed below the second fastening holes.

5. The bonding apparatus of claim 1, wherein the first unit and the second unit each extend in the first direction.

6. The bonding apparatus of claim 4, wherein a length of the first unit extending in the first direction is equal to a length of the second unit extending in the first direction.

7. The bonding apparatus of claim 1, wherein:
the first temperature control part comprises a first temperature sensor and a first resistor heating wire; and
the second temperature control part comprises a second temperature sensor and a second resistor heating wire.

8. The bonding apparatus of claim 1, wherein:
the first temperature control part penetrates through the first unit and is disposed in the first unit; and
the second temperature control part penetrates through the second unit and is disposed in the second unit.

9. The bonding apparatus of claim 1, wherein:
the second unit comprises a tip part defined in a lower portion of the second unit; and
the tip part protrudes in a direction from the second unit toward the stage.

10. The bonding apparatus of claim 9, wherein the tip part comprises a lower surface that is flat.

11. The bonding apparatus of claim 1, wherein the first unit, the second unit, or both comprises a tungsten carbide.

12. The bonding apparatus of claim 1, further comprising a head part disposed on the first unit and coupled with the first unit, wherein:
an upper surface of the stage has a flat surface defined by the first direction and a second direction intersecting the first direction; and
the head part is configured to reciprocate in a third direction intersecting the first direction and the second direction.

13. A method of manufacturing a display device, comprising:
aligning a circuit member on a preliminary display panel comprising pads on a stage;
placing a press unit comprising a first unit and a second unit above the circuit member, wherein the first unit comprises a first temperature control part and the second unit is disposed under the first unit and comprises a second temperature control part; and
pressing the circuit member and the pads using the press unit in association with bonding the circuit member to the pads, the bonding of the circuit member to the pads comprising:
adjusting a temperature of the first unit using the first temperature control part or a temperature of the second unit using the second temperature control part; and
moving the press unit downward based on determining each of the first unit and the second unit is at a respective reference temperature.

14. The method of claim 13, wherein:
the adjusting of the temperature of the first unit or the temperature of the second unit is based on obtaining or maintaining a first ratio of the temperature of the second unit to the temperature of the first unit such that the first ratio ranges from about 0.9 times to about 1.1 times a second ratio of a first thermal expansion coefficient to a second thermal expansion coefficient.

15. The method of claim 13, wherein:
the first temperature control part comprises a first temperature sensor and a first resistor heating wire;
the second temperature control part comprises a second temperature sensor and a second resistor heating wire; and
the adjusting of the temperature comprises supplying a current to the first resistor heating wire, the second resistor heating wire, or both.

16. The method of claim 13, wherein:
the second unit comprises a tip part defined in a lower portion of the second unit;
the tip part protrudes in a direction from the second unit toward the stage; and
the bonding of the circuit member comprises maintaining the tip part in contact with the circuit member such that the tip part transfers heat to the circuit member.

17. A method of manufacturing a display device, comprising:
selecting a first unit among a plurality of first units and a second unit among a plurality of second units, wherein the first unit comprises a first temperature control part and the second unit comprises a second temperature control part;
forming a press unit comprising the first unit and the second unit, wherein the second unit is coupled with a lower portion of the first unit;
aligning a circuit member on a preliminary display panel comprising pads on a stage;
placing the press unit above the circuit member; and
moving the press unit downward in association with bonding the circuit member to the pads, wherein the bonding of the circuit member to the pads comprises adjusting or maintaining the selected first unit according to a first reference temperature by the first temperature control part and adjusting or maintaining the selected second unit according to a second reference temperature by the second temperature control part.

18. The method of claim 17, wherein the forming of the press unit comprises:
placing the second unit on the lower portion of the first unit; and
inserting each of fastening members into a corresponding first fastening hole among first fastening holes defined through the first unit and spaced apart from each other in a first direction and a corresponding second fastening hole among second fastening holes defined through the second unit and spaced apart from each other in the first direction.

19. The method of claim 17, wherein:
the first temperature control part comprises a first temperature sensor and a first resistor heating wire;
the second temperature control part comprises a second temperature sensor and a second resistor heating wire; and
the adjusting or maintaining of the first unit according to the first reference temperature comprises supplying a current to the first resistor heating wire and the adjusting or maintaining of the second unit according to the second reference temperature comprises supplying a current to the second resistor heating wire.

20. The method of claim 17, wherein:
the second unit comprises a tip part defined in a lower portion of the second unit;
the tip part protrudes in a direction from the second unit toward the stage; and
the bonding of the circuit member to the pads comprises maintaining the tip part in contact with the circuit member such that the tip part transfers heat to the circuit member.
